(19) United States
(12) Patent Application Publication
(10) Pub. No.: US 2026/0295870 A1
(43) Pub. Date: Oct. 1, 2026

(54) APPARATUS SYSTEM AND METHOD FOR A CURVED VACUUM CHUCK FOR THIN SUBSTRATES

(71) Applicant: JABIL INC., St. Petersburg, FL (US)

(72) Inventors: JEROEN BOSBOOM, St. Petersburg, FL (US); MICHAEL RAY BERRY, St. Petersburg, FL (US)

(21) Appl. No.: 19/481,201

(22) PCT Filed: May 1, 2024
(86) PCT No.: PCT/US2024/027200

§ 371 Date: Nov. 4, 2025

Related U.S. Application Data
(60) Provisional application No. 63/465,315, filed on May 10, 2023.

(51) Int. Cl. B25J 15/06; B25J 17/02; H01M 50/105

(52) U.S. Cl. CPC B25J 15/0625; B25J 15/0666; B25J 15/0683; B25J 17/0241; H01M 50/105

(57) ABSTRACT

An apparatus, system and method for providing a curved vacuum chuck capable of picking and placing a thin film substrate. The embodiments include: a chuck body; a chuck platen having a curvature along at least one axis thereof; at least two rotation points integral with the chuck body and running axially along and at opposing ends of the chuck platen; and a plurality of vacuum ports on a face of the chuck platen which are applied sequentially to the thin film substrate along the axis of curvature as the chuck platen is moved downward in relation to a horizontal axis through the chuck body and is rotated about the rotation points

### CROSS-REFERENCE TO RELATED APPLICATIONS

This application claims priority to U.S. Provisional Patent Application No. 63/465,315, filed May 10, 2023, entitled: “Apparatus, System and Method for a Curved Vacuum Chuck for Thin Substrates,” the contents of which are incorporated by reference herein in their entirety.

### FIELD OF THE INVENTION

The disclosure relates generally to manufacturing, and, more particularly, to an apparatus, system, and method for a curved vacuum chuck.

### BACKGROUND

Robotic picking and placement of components often involves picking thin substrates, such as with a vacuum chuck or a lapped vacuum pad, for placement. The thin and delicate nature of such thin substrates can cause the substrates to tear, and lends itself to the trapping of gas bubbles in association with the substrates, which can significantly affect the performance of the substrate, as well as the ability to properly place the substrate.

Thin substrates must be placed in numerous contexts, such as particularly in the assembling of electronics. By way of example, assembling pouch battery layers is a typical application. However, the delicate nature of such electronic assembly necessitates proper handling of thin substrates without tearing, and the picking and application of these thing substrates without gas bubbling.

Accordingly, the need exists for a method, system and apparatus for a curved vacuum chuck.

### SUMMARY OF THE DISCLOSURE

The embodiments provide an apparatus, system and method for providing a vacuum chuck capable of picking and placing a thin film substrate. The embodiments include: a chuck body; a chuck platen having a curvature along at least one axis thereof; at least two rotation points integral with the chuck body and running axially along and at opposing ends of the chuck platen; and a plurality of vacuum ports on a face of the chuck platen which are applied sequentially to the thin film substrate along the axis of curvature as the chuck platen is moved downward in relation to a horizontal axis through the chuck body and is rotated about the rotation points.

Thus, in satisfaction of the aforementioned need, the embodiments provide a method, system and apparatus for a curved vacuum chuck.

### BRIEF DESCRIPTION OF THE DRAWINGS

This disclosure is illustrated by way of example and not by way of limitation in the accompanying figure(s). The figure(s) may, alone or in combination, illustrate one or more embodiments of the disclosure. Elements illustrated in the figure(s) are not necessarily drawn to scale. Reference labels may or may not be repeated among the figures to indicate corresponding or analogous elements.

FIG. 1 illustrates aspects of an exemplary embodiment of the present invention;

FIG. 2 illustrates aspects of an exemplary embodiment of the present invention;

FIGS. 3A and 3B illustrate aspects of the embodiments;

FIGS. 4A and 4B illustrate aspects of the embodiments;

FIGS. 5A and 5B illustrate aspects of an exemplary embodiment of the present invention.

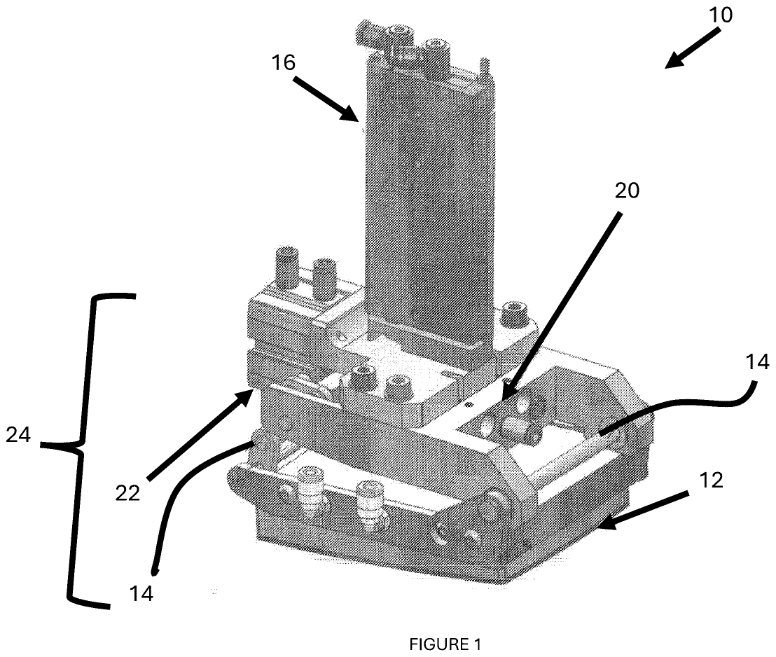

### DETAILED DESCRIPTION

The figures and descriptions provided herein may have been simplified to illustrate aspects that arc relevant for a clear understanding of the herein described devices, systems, and methods, while eliminating, for the purpose of clarity, other aspects that may be found in typical similar devices, systems, and methods. Those of ordinary skill may recognize that other elements and/or operations may be desirable and/or necessary to implement the devices, systems, and methods described herein. But because such elements and operations are well known in the art, and because they do not facilitate a better understanding of the present disclosure, a discussion of such elements and operations may not be provided herein. However, the present disclosure is deemed to inherently include all such elements, variations, and modifications to the described aspects that would be known to those of ordinary skill in the art.

The terminology used herein is for the purpose of describing particular example embodiments only and is not intended to be limiting. For example, as used herein, the singular forms “a”, “an” and “the” may be intended to include the plural forms as well, unless the context clearly indicates otherwise. The terms “comprises,’ ‘comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on”, “engaged to”, “connected to” or “coupled to” another element or layer, it may be directly on, engaged, connected or coupled to the other element or layer, or intervening elements or layers may be present. In contrast, when an clement is referred to as being “directly on,” “directly engaged to”, “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc., may be used herein to describe various elements, components, regions, layers and/or sections, these elements, components, regions, layers and/or sections should not be limited by these terms. These terms may be only used to distinguish one element, component, region, layer or section from another element, component, region, layer or section. That is, terms such as “first,” second,” and other numerical terms, when used herein, do not imply a sequence or order unless clearly indicated by the context. Thus, a first element, component, region, layer or section discussed below could be termed a second element, component, region, layer or section without departing from the teachings of the exemplary embodiments.

In the disclosed embodiments, the surface of a picking/placing vacuum chuck may be curved. This curved chuck may optimize the picking of, and transfer/placement of, a thin substrate to other component surfaces, and may minimize the trapping of air or gases between the layers of substrates, and between a thin substrate and the chuck or the surface onto which the thin substrate is to be placed.

When fragile or thin material layers are placed on adjacent surfaces, a curved surface for the pick chuck fully supports the layer being added. A curved chuck surface also better supports the load being applied to adhere the layer.

The brittle layers of a thin substrate or substrates don't tolerate repeated flexure, especially in countervailing directions, well. The profile of the disclosed curved chuck is ideal in light of this fact, as a curved chuck can better apply gentle and more unidirectional and uniform pressure for full support of a thin substrate/thin layers as the chuck is pressed on.

An embodiment of the curved vacuum chuck may include an integral 5 to 40 micron level filter surface to provide filtering to avoid contaminating upstream vacuum generators, tubing, and valves. The chuck may be formed from a porous material, such as from porous ceramic like silicon nitride or porous aluminum. The typical porosity of the filter medium is 5, 10, 20, 30 or 40 microns.

In additional embodiments, sintered stainless-steel membrane elements may be placed behind the vacuum pads and in front of the vacuum supply gallery in order to prevent contamination of the upstream valves. In these cases, billet aluminum with finely drilled galleries and hard anodized or nickel plating may be used.

A sintered face may act as a filter and moderates airflow through the sintered membrane-chuck face, even when it is only partially covered. More specifically, the airflow flow through the filter membrane is naturally slowed down and creates a differential from atmospheric pressure. Accordingly, a partially covered chuck membrane is capable of holding parts.

Yet further embodiments may use an open cell neoprene membrane with a perforated but smooth face to conform to the work surface as the chuck deposits the cell layer. The curvature may be in two axes, thus allowing the membrane to simultaneously evacuate gas layers/pockets from the center to the periphery of the substrate layers, forward and outward from the center contact patch.

As referenced above, assembling pouch battery layers is a typical application for a chuck such as that disclosed. Particularly in such processes in which the automated transfer of a solid-state lithium-ion battery pouch layer benefits from selective adhesion during transfer in a lamination process, the curved vacuum face geometry of the embodiments forces out and prevents gassing between the layers.

The dynamic handling qualities of a curved chuck configuration are ideal for the transfer of thin films to a tacky surface, like a battery stack. The curved chuck may have multiple vacuum zones to allow the gradual pick or release of films. This enables a porous, curved face to transfer pouch layer sheets to a battery stack, and through the robotic or dedicated axis elliptical path it is guided through. The curved chuck face also squeezes out air\gas pockets in the battery stack, as mentioned, which otherwise are trapped between layers and thus become very difficult to remove.

The curved chuck face may benefit from additional compliance so as to improve adhesion between placed layers. Added compliance may alleviate pressure hot spots caused by minor misalignments. This added compliance may take the form of a layer of elastomer between the robot arm and end effector tooling. In this case, the surfaces contact the compliance enables more complete contact between layers. The elastomer may additionally or alternatively be used on the chuck base tooling to enable the same degree of compliance.

In order to help transfer thin film battery layers from the chuck face to the “stack”, a stripper frame may be placed around or over sections of the chuck. The stripper plate may be thin and deformable enough to be held down by the vacuum adhesion of the battery layer. Removing vacuum may then allow the stripper element to spring away and slowly remove the film or layer without introducing a back wash of gas from the chuck, thus reducing potential contamination.

Even filtered chucks may accumulate debris over time and deposit it to the product. To address this, an automated chuck cleaning station may clean the robot mounted vacuum chuck, such as by flushing the surface in a sealed or enclosed IPA shower with a backflow of nitrogen gas through the porous membrane. The curved vacuum chuck may be periodically and automatically serviced at this chuck cleaning station.

In order to lower automation costs, the vacuum chuck may mounted to a vertical slide. The vacuum chuck pivots with a four-bar linkage. This enables the curved vacuum chuck to roll against a perpendicular target surface, such as to deposit or pick the layer gradually without bunching or stretching the layer as the pick chuck travels downward or upward.

The vacuum chuck platen may additionally be equipped with an extension and retraction cylinder. The extension cylinder may be regulated to deliver a tunable delivery load. The retraction cylinder may keep the platen from touching the work surface by keeping the platen retracted as the vertical slide retracts.

The vertical motion of the chuck may enable lower cost 2, 3 and 4 axis robots to accomplish the motion of a 5 or 6 axis robot at a lower cost. By arraying side by side chuck modules, multiple pick and place heads may be shared on one robot. A 5 to 6 axis robot would struggle with handling more than one vacuum chuck, in part due to the need for compliance between chucks, and due to the sensitivity and relative instability of joint deflection loads.

In addition to the compliant curved face of the vacuum chuck, a sliding bed may be used to support the work piece and enable it to move in line with the x-axis curvature of the chuck. The horizontal moving axis is parallel to the x-axis of the chuck curvature. In this exemplary embodiment, as the vertical axis of the head extends, the curvature of the chuck will incrementally slide the work piece back. This ensures a tight bond between the work piece and chuck, and prevents buildup of gas pockets.

In other configurations, the work head may be programmed to travel in accordance with the chuck curvature. That is, as the chuck moves downward, the work head travels forward and rotates along its curvature.

In yet another configuration, the curved vacuum chuck acting as an end effector may be mounted on a 4-axis robot in order to cancel the relative motion between the chuck and work piece using a continuous pitch and traverse adjustment during placement. Of note, such a curved chuck does not need a 4-bar linkage. The chuck offset and virtual roll motion is programmed into the robot path instead of providing compliance in the x axis.

As discussed above, the embodiments provide an improved chuck having a curvature so as to tightly pick and place thin films, with removal of bubbling and gases in the pick and placement of said thin film. As will be appreciated by the skilled artisan, the thin film picked may be placed in an opposite manner in ones of the embodiments, such that the rolling of the curvature across the thin film during picking is the opposite of the curvature roll executed during placement.

Moreover, and as discussed further below, the pick plate may be a linear slide, such that when the curved chuck travels there-across, the plate may shift left and right as shown. That is, the pitch change of the curved chuck may translate the pick plate in the X axis. Thereby, at least one degree of freedom may be provided for the pick chuck. Of course, those skilled in the art will appreciate that the degrees of freedom provided by a pick plate may be application specific, such that multiple degrees of freedom and translation may be provided.

As such, a thin film/membrane may be placed upon a translating pick plate, such as may be formed of glass. The curved chuck may be then moved in the Z axis toward the thin film, while the curved chuck rotates along its curvature in the X and/or Y axes using, for example, the disclosed hinge system.

As shown more particularly in Figure l, the curved chuck 10 may include a vacuum chuck plate 12 associated with one or more hinges 14 proximate to the outer corners thereof. A vertical linear actuator 16 may raise and lower the chuck plate 12 into position for a pick or a place, and the chuck hinges 14 may rotate the plate 12, and/or the plate 12 may be extended or lifted, upon actuation of one or more chuck extend 20 and/or chuck lift cylinders 22 embedded atop the body 24 of the chuck 10.

Thereby, the vertical linear actuator 16 may raise and lower the curved chuck plate 12. The chuck extension cylinder 20 may actuate the chuck plate using a downward press upon a thin film. The chuck lift 22 may raise and keep the chuck plate 12 retracted.

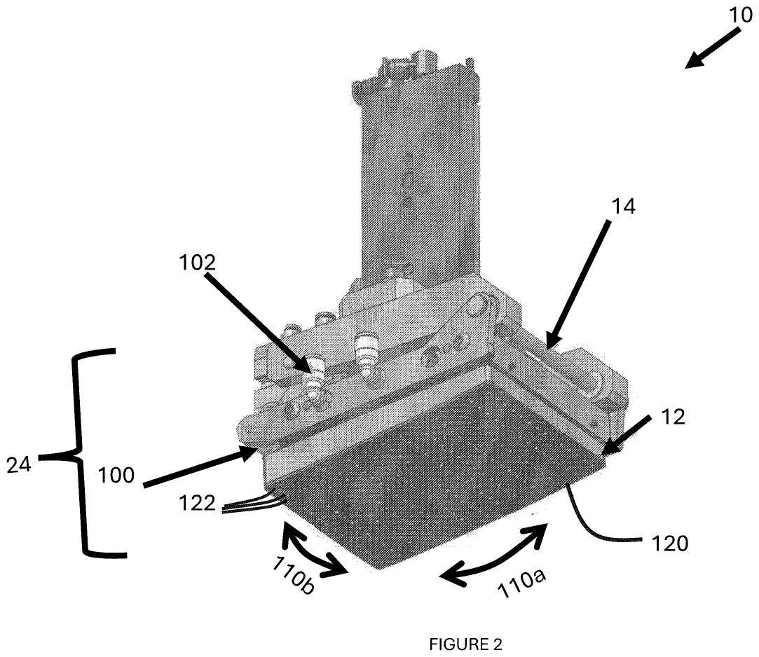

FIG. 2 illustrates a bottom view of a curved vacuum chuck assemblage 10. A linkage assembly 100 may be provided in association with the chuck body 24, such that power and vacuum, such as via vacuum ports 102, are maintained to the chuck plate 12 during raising, lowering, and rotation along the curvature of the chuck, and such as may include the hinges/pivots 14.

As shown, the curvature of the chuck platen 12 in the disclosure may be along both the length I and the width I or along one of the length or the width, of the vacuum chuck platen. Of note, and to improve the adhesion of the chuck platen 12, since the chuck platen itself may be of a relatively frictionless surface, such as stainless steel, a conforming gasket 120 with vacuum perforations 122 there through may be provided upon that portion of the chuck plate 12 that contacts the thin film. The gasket 120 may be formed, for example, of foam, such as to optimize conformance to the chuck plate 12, such as particularly in a multi-axis curvature (110a/b) embodiment.

As referenced, one or more vacuum ports 102 may be supplied from the upper part of chuck body 24 to supply vacuum to the chuck platen 12, and the one or more pivot hinges 14 may additionally be supplied to allow the chuck plate 12 to rotate its curvature along a flat surface as pressure is applied from above the chuck plate.

Needless to say, the advantage of a multi-axis curvature, i.e., a curvature along the length and width, of the chuck plate is that, as pressure is applied to the chuck plate, it will press out bubbles and gas from a center point along multiple axes outward from that center point, thereby forcing bubbles and gas to the edge of the pressed thin film, and then outward from those edges. Thus, it may be of particular import that the gasket complies strictly to the shape imparted by the chuck plate, in order to provide optimal smoothing of the thin film, and more particularly elimination of gas bubbles associated therewith, as pressure is applied to the thin film.

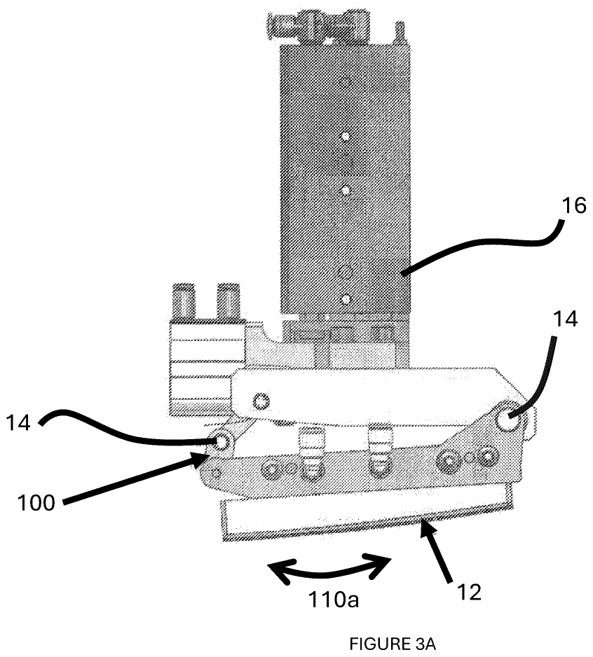

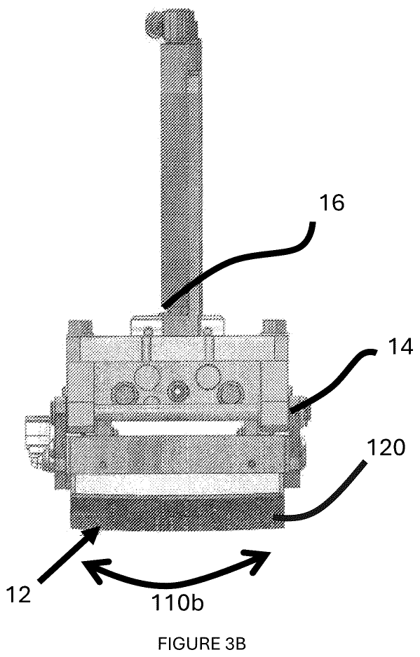

FIGS. 3A and 3B show a side view and a front view of a chuck plate 12 having a multi-axis curvature. In the illustration, the chuck plate 12 is curved along both its length and its width 110a, I Additionally shown is the conforming foam gasket 120 following the curvature imparted by the chuck platen 12. Also illustrated in FIG. 3 is the linkage assembly 100, front hinge 14, the location of the vacuum ports, and the linear vertical actuator 16.

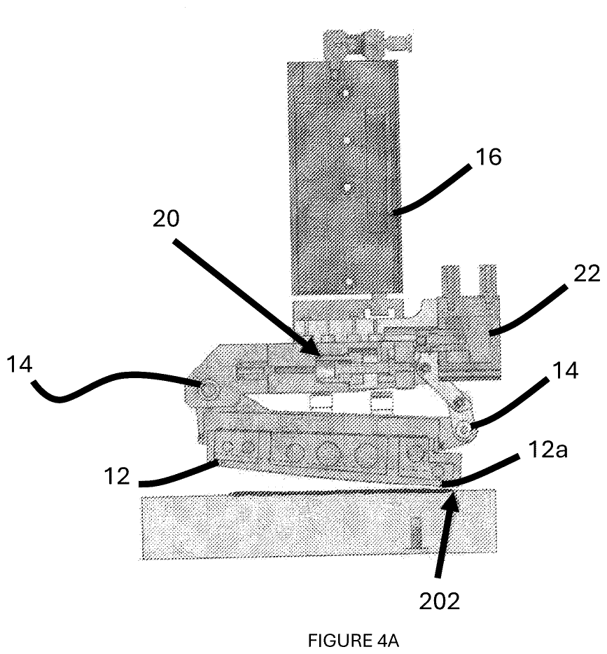

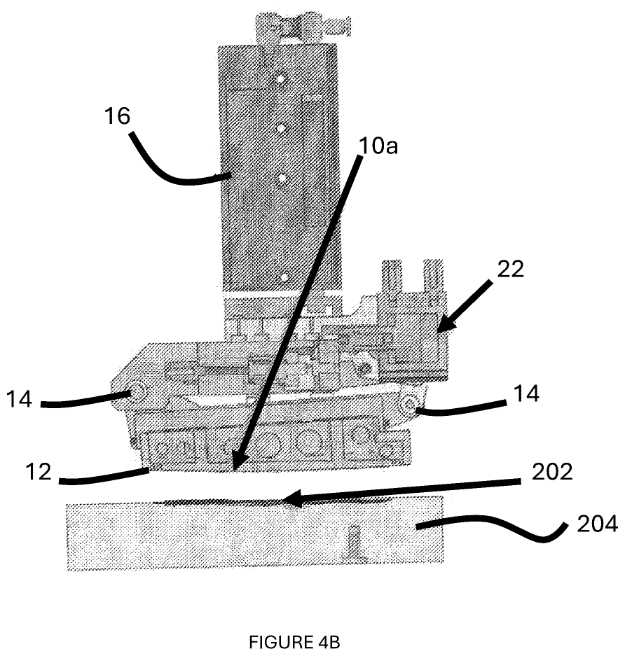

FIGS. 4A and 4B provide cutaway views of the curved chuck plate 12 in use. As shown in FIG. 4A, the chuck extension cylinder 20 lowers the chuck plate 12, such that a thin film/substrate 202 place or pick posture begins with the chuck plate extended opposite its front hinge 14 side. That is, the heel 12a of the plate contacts the thin film 202 first.

As shown in FIG. 4B, the spherically curved 110a face of the chuck plate 12 then rolls the substrate 202 onto the work piece 204 for placement, at which time the vacuum may be turned off, either fully or synchronously with the execution of the roll along curvature I I( )a. After placement, the chuck lift cylinder 22 may be actuated in order to lift the chuck plate 12 and avoid further contact with the placed thin film 202.

Needless to say, in the embodiments shown, trapped gases are pushed along the thin film as the chuck is rolled and pressure is applied to the substrate, thereby escaping the trapped gases. Moreover, the work piece face shown may travel, or translate, such as in the X axis instead of or while the chuck plate is rotating, in additional exemplary embodiments and as referenced hereinabove.

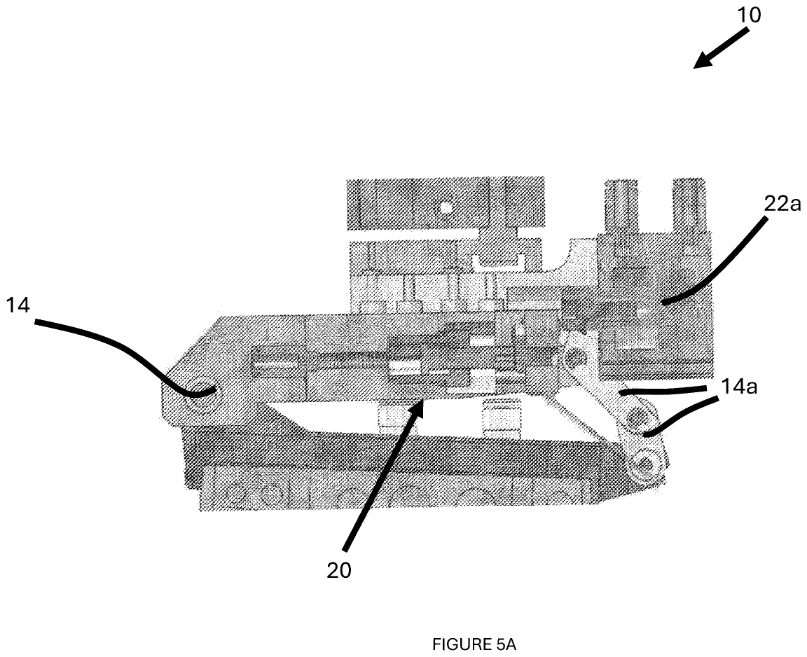

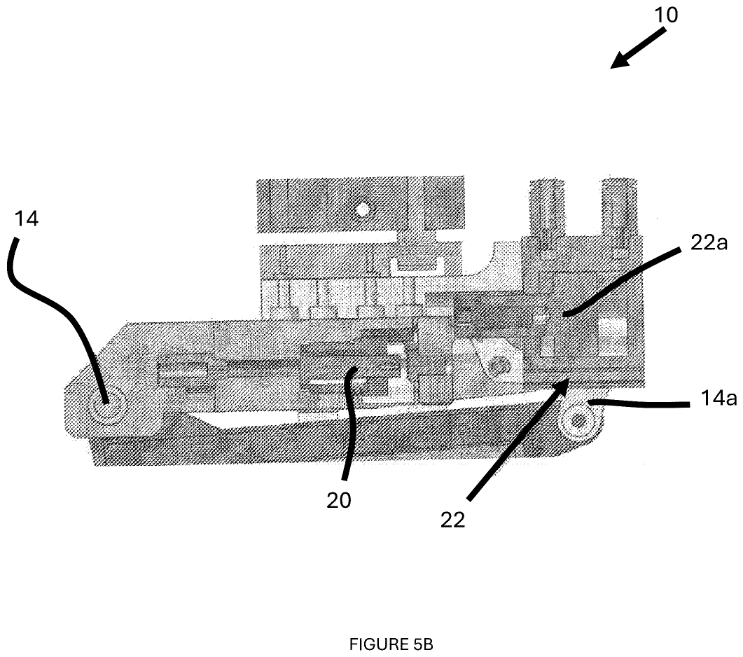

FIGS. 5A and 5B are cutaway views showing the motions of the chuck assemblage 10 during the actuation process. When the chuck plate is extended, for example, FIG. 5A illustrates extension of a chuck extension cylinder 20, such as a single acting spring return cylinder. This extends the hinged arm 14a of the chuck body, which thereby rotates the “back” of the chuck downward about the hinge 14 on the “front” of the chuck, as shown. Thereby, extension or retraction of the chuck cylinder 20 lifts or lowers the chuck plate 12. Similarly, FIG. 5B illustrates the extension of the double acting lift cylinder 22a, which thereby pressures the spring return cylinder 20 and raises the chuck plate 12 on its “back” side. That is, retraction of the raising and lowering chuck cylinder 22a causes a parallel retraction of the vacuum chuck plate. Relatedly, downward force may be supplied by actuation of the vertical actuator 16 and/or of the vacuum chuck extender.

As noted throughout, conforming foam may be provided for added compliance of the chuck plate, as well as for improved adhesion during vacuum. Of note, the vacuum holes through the conforming membrane should be kept to a relatively small size, such as to avoid “sucking up” the thin film/membrane being picked or placed.

In the foregoing Detailed Description, it can be seen that various features are grouped together in a single embodiment for the purpose of clarity and brevity of the disclosure. This method of disclosure is not to be interpreted as reflecting an intention that the embodiments require more features than are expressly recited herein. Rather, the disclosure is to encompass all variations and modifications to the disclosed embodiments that would be understood to the skilled artisan in light of the disclosure.

What is claimed is:

1. A vacuum chuck capable of picking and placing a thin film substrate, comprising:
a chuck body;
a chuck platen having a curvature along at least one axis thereof;
at least two rotation points integral with the chuck body and running axially along and at opposing ends of the chuck platen; and
a plurality of vacuum ports on a face of the chuck platen which are applied sequentially to the thin film substrate along the axis of curvature as the chuck platen is moved downward in relation to a horizontal axis through the chuck body and is rotated about the rotation points.

2. The vacuum chuck of claim 1, wherein the plurality of vacuum ports are additionally actuated sequentially.

3. The vacuum chuck of claim l, wherein the plurality of vacuum ports are unapplied inversely to the application sequence.

4. The vacuum chuck of claim 3, wherein the plurality of vacuum points are additionally turned off according to the inverse sequence.

5. The vacuum chuck of claim l, wherein the chuck platen has a second curvature along a second axis perpendicular to the at least one axis.

6. The vacuum chuck of claim 1, further comprising an integral filter on the face of the platen that conforms to the curvature.

7. The vacuum chuck of claim 6, wherein the integral filter is a 5 to 40-micron level filter.

8. The vacuum chuck of claim 6, wherein a porosity of the integral filter medium is 5, 10, 20, 30 or 40 microns.

9. The vacuum chuck of claim l, wherein the thin film substrate is a pouch battery layer.

10. The vacuum chuck of claim l, wherein the thin film substrate is a lamination.

11. The vacuum chuck of claim 1, wherein the face comprises an added compliant layer that conforms to the curvature.

12. The vacuum chuck of claim 11, wherein the added complaint layer comprises foam.

13. The vacuum chuck of claim 1, further comprising a stripper frame that at least partially sweeps the face to aid in removal of the thin film upon deactivation of the plurality of the vacuum ports.

14. The vacuum chuck of claim 13, wherein the stripper frame is deformable.

15. The vacuum chuck of claim 1, further comprising an extension cylinder connective with the chuck platen and integral to the chuck body.

16. The vacuum chuck of claim 15, wherein extension of the extension cylinder rotates the chuck platen about the rotation points in a first direction along the curvature.

17. The vacuum chuck of claim 16, wherein retraction of the extension cylinder rotates the chuck platen in a second direction opposite the first direction.
